(19) United States
(12) Patent Application Publication
(10) Pub. No.: US 2012/0119199 A1
(43) Pub. Date: May 17, 2012

(54) ORGANIC ELECTROLUMINESCENT DISPLAY DEVICE

(75) Inventors: Ken Okamoto, Osaka (JP); Yoshimata Fujita, Osaka (JP)

(73) Assignee: SHARP KABUSHIKI KAISHA, Osaka (JP)

(21) Appl. No.: 13/387,084

(22) PCT Filed: Mar. 2, 2010
(86) PCT No.: PCT/JP2010/053353

§ 371 Date: Jan. 25, 2012

(30) Foreign Application Priority Data
Jul. 29, 2009 (JP) 2009-176872

(51) Int. Cl. H01L 51/52

(52) U.S. Cl. 257/40; 257/E51.018

(57) ABSTRACT

The present invention provides an organic EL display device that has high out-coupling efficiency of light. The organic EL display device includes a semi-transparent cathode having high light reflectivity, high light transparency, low light absorptivity, and good electron injection properties. The organic EL display device of the present invention includes an organic EL element that includes an anode, an organic layer, an electron injection layer, and a cathode stacked in this order toward a viewing side, wherein the cathode is a thin film made of silver or a silver alloy, the electron injection layer includes a first electron injection layer arranged on the organic layer side and a second electron injection layer arranged on the cathode side, the first electron injection layer is formed as a thin film containing lithium fluoride, the second electron injection layer is formed as a thin film containing a magnesium-silver alloy that has a silver concentration of more than 70 wt % and less than 100 wt %, and an average total film thickness of the cathode and the electron injection layer is not less than 15 nm and not more than 25 nm.

### TECHNICAL FIELD

The present invention relates to an organic electroluminescent display device. More specifically, the present invention relates to a top emission organic electroluminescent display device.

### BACKGROUND ART

Organic electroluminescent (hereinafter also referred to as organic EL) display devices can be roughly classified into top emission ones and bottom emission ones based on the light extraction directions. Top emission organic EL display devices are widely used because they have a high aperture ratio compared to bottom emission organic EL display devices.

A top emission organic EL display device includes, on an element substrate such as a glass substrate, an organic EL element that has a metal electrode (anode), an organic layer including a light-emitting layer, and a transparent electrode (cathode) in this order toward a viewing side. The light generated in the light-emitting layer is emitted out of the light-emitting layer toward the direction opposite to the element substrate, thereby being emitted out of the element. Meanwhile, a portion of the light is reflected on the anode, passes through the organic layer and the cathode, and is then emitted out of the element.

Here, the light reflected on the anode is guided under an influence of total reflection, and thus the proportion of the light that can be extracted out of the element (hereinafter, such a proportion is also referred to as out-coupling efficiency of light) is only about 20% to 25%, which is one of the reasons that the light-emitting efficiency of the organic EL display devices is insufficient.

Patent Document 1, for example, has proposed a technique of forming a cathode from a metal electrode having transparency (hereinafter, also referred to as a semi-transparent cathode) instead of a transparent electrode such as indium tin oxide (ITO), and allowing a portion of the light to be reflected between the semi-transparent cathode and the anode before being emitted to the outside.

Patent Document 1 has proposed semi-transparent cathodes such as one made of a magnesium-silver alloy (Mg—Ag alloy) and one formed as a laminated film of Mg—Ag alloy and silver (Ag). In an organic EL display device including a semi-transparent cathode, the light generated in the light-emitting layer is classified as the light passing through the semi-transparent cathode and being emitted to the outside; the light being reflected on the anode, passing through the organic layer and the semi-transparent cathode, and being emitted to the outside; and the light being reflected in the interface between the organic layer and the semi-transparent cathode, further reflected on the anode, passing through the organic layer and the semi-transparent cathode, and being emitted to the outside. Such use of optical interference between the anode and the semi-transparent electrode enables to collect the light generated in the light-emitting layer in the extraction direction, increasing the out-coupling efficiency of the light.

Since optical interference occurs between the anode and the semi-transparent electrode in an organic EL display device having the above structure, the difference of the light intensities becomes clear at different wavelengths, and therefore the organic EL display device can deepen the color of the extracted light. Further, semi-transparent cathodes made of an Mg—Ag alloy, Ag, or the like can be formed by the vacuum deposition method, sputtering method, or the like, which means that they can be formed at lower temperatures than those for formation of transparent cathodes made of ITO or the like. Thereby, deterioration of the organic layer caused by heat can be prevented, and organic EL display devices having high luminance can be produced at a high yield.

Patent Document 1: JP 2006-344497 A

### SUMMARY OF THE INVENTION

In order to increase the out-coupling efficiency of an organic EL display device including a semi-transparent electrode, it is important to increase the light reflectance in the interface between the semi-transparent electrode and the organic layer, and suppress the light absorptance of the semi-transparent electrode.

Among the above materials of semi-transparent electrodes, Ag is a substance having high light reflectivity and low light absorptivity; Ag, however, has low electron injection properties, and a semi-transparent electrode made only of Ag cannot provide sufficient out-coupling efficiency of light. In contrast, Mg contained in an Mg—Ag alloy is a substance that has higher electron injection properties than Ag, but has low light reflectivity and high light absorptivity. Hence, depending on the composition of the Mg—Ag alloy, sufficient out-coupling efficiency of light may not be achieved.

Further, generation of a sufficient amount of light in the light-emitting layer is also required to increase the out-coupling efficiency of light. A semi-transparent cathode made of an Mg—Ag alloy has higher electron injection properties than Ag as described above, but still has insufficient electron injection efficiency for the organic layer. Such a semi-transparent cathode is therefore desired to have higher light-emitting efficiency.

As above, the out-coupling efficiency of light is different depending on factors such as the composition and structure of the semi-transparent electrode in the current state of the art. Thus, an organic EL display device having stable, high out-coupling efficiency of light is desired.

The present invention has been made in view of the above current state of the art, and aims to provide an organic EL display device that has high out-coupling efficiency of light. The organic EL display device includes a semi-transparent cathode having high light reflectivity, high light transparency, low light absorptivity, and good electron injection properties.

The present inventors have made various studies on top emission organic EL display devices having high out-coupling efficiency of light, and have focused on the effect of employing a semi-transparent electrode as a cathode for increasing the out-coupling efficiency of light. As a result, the present inventors have found that the following structure enables to solve the above problems admirably. That is, a semi-transparent electrode should have a structure including a cathode made of silver or a silver alloy, a first electron injection layer arranged on the organic layer side, and a second electron injection layer arranged on the cathode side. Based on such a structure of the semi-transparent electrode, high electron injection properties can be achieved by forming the first electron injection layer as a thin film containing lithium fluoride. Further, high light reflectance and low light absorptance can be achieved by forming the second electron injection layer from an alloy that is obtained by blending silver having high light reflectance and low light absorptance and magnesium having low work function at a certain ratio. Furthermore, the electron injection properties can be increased by controlling the composition of the second electron injection layer and the film thickness of the semi-transparent electrode. These findings have led to the present invention.

That is, the present invention relates to an organic electroluminescent display device, including an organic electroluminescent element that includes an anode, an organic layer, an electron injection layer, and a cathode stacked in this order toward a viewing side, wherein the cathode is a thin film made of silver or a silver alloy, the electron injection layer includes a first electron injection layer arranged on the organic layer side and a second electron injection layer arranged on the cathode side, the first electron injection layer is formed as a thin film containing lithium fluoride, the second electron injection layer is formed as a thin film containing a magnesium-silver alloy that has a silver concentration of more than 70 wt % and less than 100 wt %, and an average total film thickness of the cathode and the electron injection layer is not less than 15 nm and not more than 25 nm.

In the case that the alloy constituting the second electron injection layer has a silver concentration of not more than 70 wt % in atomic composition, the light reflectance of the electron injection layer decreases and the light absorptance also increases, leading to a decrease in the out-coupling efficiency of light. In contrast, in the case that the silver concentration is 100 wt %, the electron injection properties decrease.

In the case that the average total film thickness of the cathode and the electron injection layer is beyond the range of 15 nm to 25 nm, the power efficiency decreases to lower the light-emitting efficiency of the light-emitting layer.

The structure of the organic electroluminescent display device of the present invention is not particularly limited as long as the display device includes the above components as essential components.

In the organic electroluminescent display device according to the present invention, an average film thickness of the second electron injection layer is preferably not less than 0.5 nm and not more than 1.5 nm. Such a structure allows the electron injection layer to have both high light reflectance and low light absorptance, and maintain the electron injection properties.

Also, an average total film thickness of the cathode and the electron injection layer is preferably not less than 17 nm and not more than 23 nm. Such a structure enables to provide an organic electroluminescent display device having higher out-coupling efficiency of light.

Here, in the case that the cathode is formed as a thin film containing a magnesium-silver alloy that has a silver concentration of more than 70 wt % and less than 100 wt %, provided that the concentration is not less than the silver concentration of the second electron injection layer, the high concentration silver contributes to an increase in the light reflectance and suppression of the light absorptance, and magnesium contributes to an increase in the electron injection properties. Accordingly, an organic electroluminescent display device having high out-coupling efficiency of light can be produced.

That is, preferred structures of the semi-transparent electrode according to the present invention include ones in which the first electron injection layer/second electron injection layer/cathode components are lithium fluoride/magnesium-silver alloy/silver or lithium fluoride/magnesium-silver alloy/magnesium-silver alloy.

The above respective structures may be appropriately combined as long as the combination does not go beyond the scope of the present invention.

### Effect of the Invention

The organic EL display device of the present invention can have high reflectance and low absorptance for the light generated in the light-emitting layer and have high electron injection properties for the light-emitting layer because the cathode is made of silver or a silver alloy and the electron injection layer includes the following layers: a first electron injection layer that is formed as a thin film containing lithium fluoride and is arranged on the anode side; and a second electron injection layer that is formed from a magnesium-silver alloy having a specific composition and is arranged on the cathode side. Further, the organic EL display device can have high out-coupling efficiency of light because controlling the average total film thickness of the cathode and the electron injection layer enables to achieve high electron injection properties while maintaining the light transmittance at a required level.

### BRIEF DESCRIPTION OF DRAWINGS

FIG. 1 is a vertical schematic cross-sectional view illustrating the structure of an organic EL display device according to a first embodiment.

FIG. 2 is a vertical schematic cross-sectional view illustrating the structure of an EOD.

FIG. 3 is a graph illustrating the relation between the composition and current density of each electron injection layer.

FIG. 4 is a graph illustrating the drive voltage, current efficiency, and power efficiency of each element.

FIG. 5 is a graph illustrating the relation between the average film thickness and power efficiency of each second electron injection layer.

FIG. 6 is a graph illustrating the relation between the Ag concentration and power efficiency of an Mg—Ag alloy.

FIG. 7 is a graph illustrating the relation between the average thickness and power efficiency of a semi-transparent electrode.

### MODES FOR CARRYING OUT THE INVENTION

Hereinafter, the present invention will be described in more detail based on an embodiment with reference to drawings. The embodiment, however, is not intended to limit the present invention.

### First Embodiment

FIG. 1 is a vertical schematic cross-sectional view illustrating the structure of an organic EL display device 100 according to a first embodiment of the present invention. In FIG. 1, the organic EL display device 100 has a structure in which a substrate 10, an anode 11, an organic layer 12, an electron injection layer 13, and a cathode 15 are arranged in this order toward the viewing side. The electron injection layer 13 consists of a first electron injection layer 13a consisting of a lithium fluoride (LiF) layer and a second electron injection layer 13b made of an Mg—Ag alloy. The organic layer 12 includes a hole injection layer 21, a hole transport layer 22, a light-emitting layer 23, and an electron transport layer 24.

The substrate 10 can be, for example, a glass substrate, a resin substrate (e.g. plastic film), or a semiconductor substrate (e.g. silicon wafer). The material of the substrate 10 is not particularly limited, and may be appropriately selected according to the need. The substrate may have a single-layer structure or a stacked structure.

The anode 11 is formed as a metal thin film having conductivity. The material of the anode 11 is not particularly limited, but is preferably a material having high light reflectance, such as aluminum (Al), Ag, platinum (Pt), nickel (Ni), and gold (Au), in terms of increasing the out-coupling efficiency of light. For efficient hole injection to the organic layer 12, the anode 11 may have a structure in which a transparent conductive oxide having a high work function, such as ITO and indium zinc oxide (IZO), is stacked on the material having high light reflectance. These materials are formed into films by methods such as the vacuum deposition method, the electron beam evaporation method, the ion plating method, the laser ablation method, and the sputtering method.

The hole injection layer 21 is also referred to as an anode buffer layer, and has a function of increasing the hole injection efficiency by bringing the energy levels of the anode 11 and the organic layer 12 closer to each other. Examples of the material of the hole injection layer 21 include triazole derivatives, oxadiazole derivatives, imidazole derivatives, polyaryl alkane derivatives, pyrazoline derivatives, phenylenediamine derivatives, oxazole derivatives, styryl anthracene derivatives, fluorenone derivatives, hydrazone derivatives, and stilbene derivatives.

The hole transport layer 22 has a function of increasing the hole transport efficiency from the anode 11 to the light-emitting layer 23. Examples of the material of the hole transport layer 22 include porphyrin derivatives, aromatic tertiary amine compounds, styryl amine derivatives, polyvinyl carbazole, poly-p-phenylene vinylene, polysilane, triazole derivatives, oxadiazole derivatives, imidazole derivatives, polyaryl alkane derivatives, pyrazoline derivatives, pyrazolone derivatives, phenylenediamine derivatives, arylamine derivatives, amine-substituted chalcone derivatives, oxazole derivatives, styryl anthracene derivatives, fluorenone derivatives, hydrazone derivatives, stilbene derivatives, hydrogenated amorphous silicon, hydrogenated amorphous silicon carbide, zinc sulfide, and zinc selenide. Each of these materials may be used alone, or two or more of these may be used in combination.

The light-emitting layer 23 has a function of emitting light in certain color and luminance using the binding energy of holes and electrons. The material of the light-emitting layer 23 is not particularly limited, and may be a low-molecular light-emitting material (e.g. fluorescent organic materials, fluorescent organic metal compounds) or a polymer light-emitting material. Each of these may be used alone, or two or more of these may be used in combination.

Examples the fluorescent organic materials include aromatic dimethylidyne compounds such as 4,4′-bis(2,2′-diphenylvinyl)-biphenyl (DPVBi); oxadiazole compounds such as 5-methyl-2-[2-[4-(5-methyl-2-benzoxazolyl)phenyl]vinyl]benzoxazol; triazole derivatives such as 3-(4-biphenylyl)-4-phenyl-5-t-butylphenyl-1,2,4-triazole (TAZ); styrylbenzene compounds such as 1,4-bis(2-methylstyryl)benzene; thiopyrazine dioxide derivatives; benzoquinone derivatives; naphthoquinone derivatives; anthraquinone derivatives; diphenoquinone derivatives; and fluorenone derivatives. Examples of the fluorescent organic metal compounds include azomethine zinc complexes and (8-hydroxyquinolinato)aluminum complexes (Alq3). Examples of the polymer light-emitting material include poly(2-decyloxy-1,4-phenylene) (DO-PPP), poly[2,5-bis-[2-(N,N,N-triethyl ammonium)ethoxy]-1,4-phenyl-alto-1,4-phenylene]dibromide (PPP-NEt3+), poly[2-(2′-ethylhexyloxy)-5-methoxy-1,4-phenylenevinylene] (MEH-PPV), poly[5-methoxy-(2-propanoxysulfonide)-1,4-phenylenevinylene] (MPS-PPV), poly[2,5-bis-(hexyloxy)-1,4-phenylene-(1-cyanovinylene)] (CN-PPV), poly(9,9-dioctylfluorene) (PDAF), and polyspiro (PS).

The electron transport layer 24 has a function of transporting the electrons injected by the cathode 15 to the light-emitting layer 23. The material of the electron transport layer 24 is not particularly limited, and may be a material such as low-molecular materials (e.g. oxadiazole derivatives, triazole derivatives, benzoquinone derivatives, naphthoquinone derivatives, fluorenone derivatives) and polymer materials (e.g. poly[oxadiazole]). Each of these may be used alone, or two or more of these may be used in combination.

Each layer constituting the organic layer 12 may optionally appropriately contain additives such as a light-emitting aid, a charge transport material, donors and acceptors, a light-emitting dopant, a leveling agent, a charge injection material, and a binding resin (e.g. polycarbonate, polyester).

The first electron injection layer 13a has a function of injecting the electrons transported by the second electron injection layer 13b into the electron transport layer 24. The first electron injection layer 13a is made of LiF, and may also contain additive(s) such as lithium carbonate and calcium fluoride as long as the function thereof is not deteriorated. The first electron injection layer 13a preferably has an average film thickness of 0.5 nm in terms of the electron injection properties.

The second electron injection layer 13b has a function of transporting the electrons injected by the cathode 15 to the first electron injection layer 13a. The second electron injection layer 13b includes a thin film made of a magnesium-silver alloy (Mg—Ag alloy). An Mg—Ag alloy, which is a material having a low work function, can contribute to an increase in the electron injection properties for the organic layer 12 and driving of the organic EL display device 100 at low voltages. Thereby, the organic EL display device can have low power consumption, and can be driven for a long period of time.

The film thickness of the second electron injection layer 13b is not particularly limited, but the average film thickness is preferably not less than 0.5 nm and not more than 1.5 nm. Such a film thickness contributes to an increase in the power efficiency of the organic EL display device 100.

The film-forming method for each of the layers constituting the organic layer 12, the first electron injection layer 13a, and the second electron injection layer 13b is not particularly limited, and may be, for example, the vacuum deposition method using a vacuum deposition device, or the electron beam deposition method. The method may also be a wet process such as the spin coating method, the doctor blade method, the discharge coating method, the spray coating method, the ink jet method, the letterpress method, the intaglio-printing method, the screen printing method, and the micro gravure coating method.

The cathode 15 has a function of injection the electrons into the electron injection layer 13. The cathode 15 in the present embodiment is a thin film made of Ag or an Ag alloy. The Ag alloy is not particularly limited, but is preferably an Mg—Ag alloy. If the cathode 15 is formed as a thin film containing an Mg—Ag alloy, then the silver concentration in the alloy is preferably more than 70 wt % and less than 100 wt %. Such a silver concentration enables to maintain the high light reflectance and low light absorptance. Further, if the silver concentration in the alloy is not less than the silver concentration in the second electron injection layer 13b, then the electron injection properties from the cathode 15 to the second electrode injection layer 13b can be increased.

The cathode 15 can be formed by a method such as the vacuum deposition method, the electron beam deposition method, the ion plating method, the laser ablation method, and the sputtering method. Among these, the vacuum deposition method is preferred because the method has a small thermal effect on the organic layer 12 which is formed before formation of the cathode 15.

Since the cathode 15 needs to have translucency, the average film thickness of the semi-transparent electrode constituted by the electron injection layer 13 and the cathode 15 is designed to be not less than 15 nm and not more than 25 nm. The reason therefor is stated below in detail.

The organic EL display device 100 having the above structure is a top emission display device in which the holes injected by the anode 11 and the electrons injected by the cathode 15 are efficiently recombined in the light-emitting layer 23 so that light is emitted, and the emitted light is extracted from the cathode 15 side. More specifically, the light generated in the light-emitting layer 23 is divided to be the light passing through the semi-transparent cathode consisting of the first electron injection layer 13a, the second electron injection layer 13b, and the cathode 15 and being emitted to the outside; the light being reflected on the anode 11, passing through the organic layer 12 and the semi-transparent cathode, and being emitted to the outside; the light being reflected in the interface between the organic layer 12 and the semi-transparent cathode, further reflected on the anode 11, passing through the organic layer 12 and the semi-transparent cathode, and being emitted to the outside; and the light being repeatedly reflected between the electrodes more times than the above case. Such use of optical interference between the anode 11 and the semi-transparent electrode enables to collect the light generated in the light-emitting layer 23 in the light extraction direction, increasing the out-coupling efficiency of light.

Since the organic EL display device 100 having the above structure contains a large amount of silver in the cathode 15 and the second electron injection layer 13b, it is possible to achieve high light reflectance and low light absorptance regarding the light generated in the light-emitting layer 23, and thus to increase the out-coupling efficiency of light. Since the semi-transparent cathode can be formed at lower temperatures than those for formation of transparent electrodes such as an ITO electrode, the organic layer 12 can be prevented from being deteriorated, and thereby the reliability of the organic EL display device 100 can be increased.

In the above description, an example is given in which the organic layer 12 includes the hole injection layer 21, the hole transport layer 22, the light-emitting layer 23, and the electron transport layer 24. The present invention is not limited to this example, and the organic layer 12 may have a single-layer structure consisting only of the light-emitting layer 23, or a stacked layer of the light-emitting layer 23 and layer(s) having other function(s). The electron injection layer 13 may include layer(s) other than the first electron injection layer 13a and the second electron injection layer 13b.

Hereinafter, the organic EL display device 100 according to the present embodiment is described based on specific examples. First, multiple electron only devices (EODs) with electron injection layers having different compositions were produced and used in the following measurements to find the structure of the organic EL element which achieves good electron injection properties.

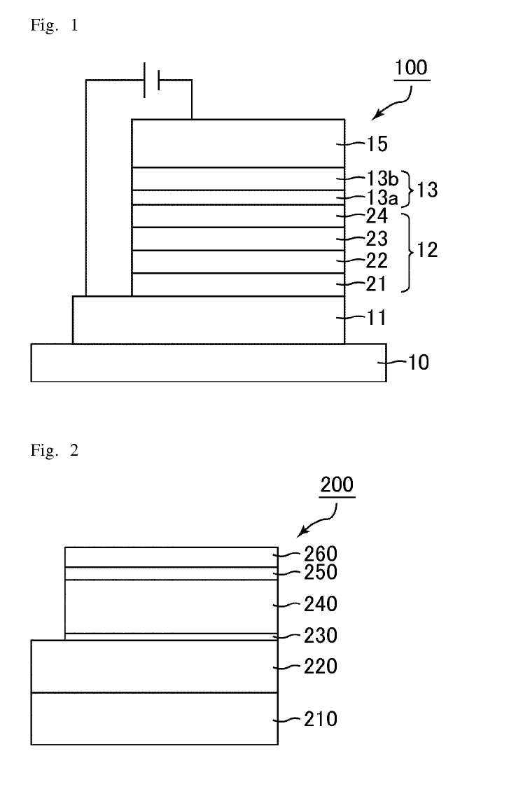

FIG. 2 is a vertical schematic cross-sectional view illustrating the structure of each EOD used in the measurement. In FIG. 2, an EOD 200 has, on the main surface of a glass substrate 210, an anode 220 made of Al, a LiF layer 230, an electron transport layer 240, an electron injection layer 250, and a cathode 260 made of Ag stacked in this order from the substrate surface side.

On the main surface of the glass substrate 210, ITO is patterned into a desired shape. The average film thickness of the anode 220 is 100 nm, the average film thickness of the LiF layer 230 is 0.5 nm, the average film thickness of the electron transport layer 240 is 100 nm, and the average film thickness of the cathode 260 is 19 nm.

The electron injection layer 250 was produced by forming a thin film having an average film thickness of 1 nm from one of five materials, Al, cesium carbonate (Cs₂CO₃), magnesium oxide (MgO), Mg—Ag (1:9), and Mg—Ag (9:1). Here, from each material, an electron injection layer with a LiF layer having an average film thickness of 0.5 nm formed on the electron transport layer 240 side of the thin film, and an electron injection layer without such a LiF layer were produced. That is, with or without the LiF layer, each electron injection layer 250 had an average film thickness of 1 nm.

The numerical values shown together with an Mg—Ag alloy indicate the atomic composition of each composition. That is, Mg—Ag (1:9) means that Mg and Ag are blended at a ratio of 1:9 based on the atomic numbers, and Mg—Ag (9:1) means that Mg and Ag are blended at a ratio of 9:1 based on the atomic numbers.

The EODs 200 having the above structures were subjected to the current density measurement upon application of 5-V voltages.

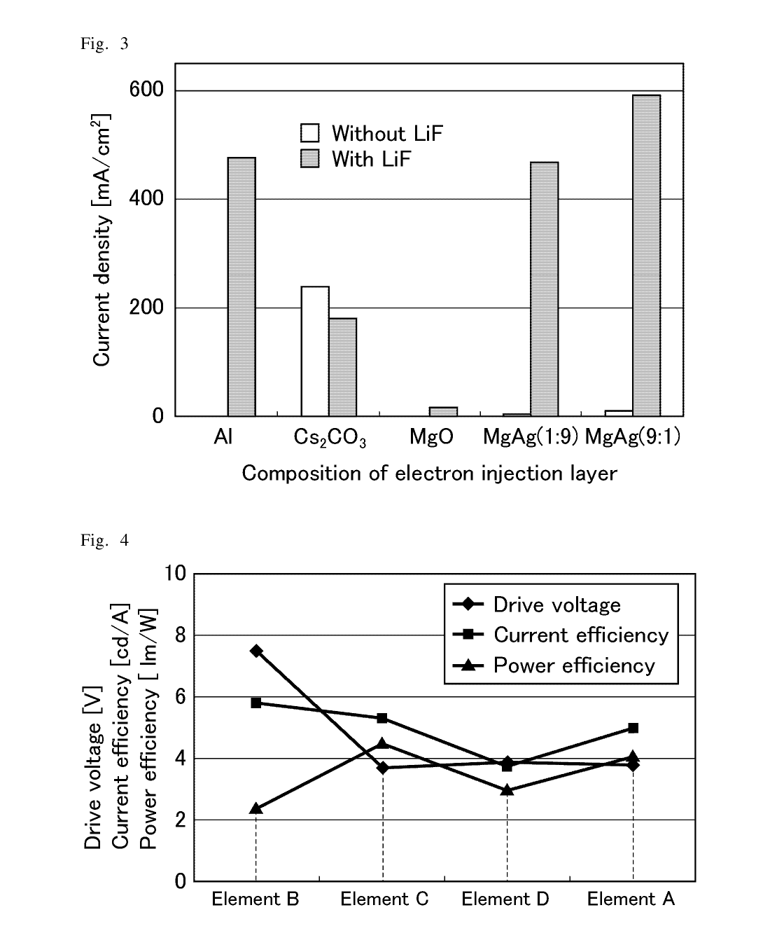

FIG. 3 shows the measurement results obtained.

FIG. 3 is a graph illustrating the relation between the composition and current density of each electron injection layer 250. In FIG. 3, a higher current density is considered to show higher electron injection properties. The graph in FIG. 3 revealed that the current density was high in the case that the electron injection layer 250 had a stacked structure of a LiF layer and an Al layer (LiF/Al), a single-layer structure of Cs₂CO₃ (Cs₂CO₃), a stacked structure of a LiF layer and Mg—Ag (1:9) (LiF/Mg—Ag (1:9)), or a stacked structure of a LiF layer and Mg—Ag (9:1) (LiF/Mg—Ag (9:1)).

Based on these results, organic EL display devices 100 were produced which included elements A to D respectively having the structures of LiF/Al, Cs₂CO₃, LiF/Mg—Ag (1:9), and LiF/Mg—Ag (9:1) as the electron injection layers 250. Each of the organic EL display devices 100 was subjected to measurements of the drive voltage [V], current efficiency [cd/A], and power efficiency [lm/W].

Specifically, first, an anode 11 and ITO wirings (not illustrated) were formed on a glass substrate as a substrate 10. The anode 11 was produced by forming Al into a film having an average film thickness of 100 nm through the sputtering method. The ITO wirings were produced on the anode 11 by forming ITO into a film having an average film thickness of 10 nm through the sputtering method, and patterning the film into a desired shape by a method such as photolithography.

Subsequently, the hole injection layer 21 and the hole transport layer 22 were formed. The hole injection layer 21 was formed as a film having an average film thickness of 100 nm by the vacuum deposition method. The hole transport layer 22 was produced by forming 4,4′-bis[N-(1-naphthyl)-N-phenylamino]biphenyl (α-NPD) into a film having an average film thickness of 10 nm by the vacuum deposition method at a deposition rate of 1 Å/sec.

The light-emitting layer 23 was then formed. The light-emitting layer 23 was produced by forming a host material and a blue light-emitting dopant material into a thin film having an average film thickness of 30 nm by the co-deposition method. The deposition rate of the host material was 1 Å/sec, and the deposition rate of the light-emitting dopant material was 0.1 Å/sec. Here, the host material was formed into a film of 10 nm as a block layer.

Next, the electron transport layer 24 was formed. The electron transport layer 24 was formed as a thin film having an average film thickness of 30 nm by the vacuum deposition method.

The first electron injection layer 13a was then formed. The first electron injection layer 13a was produced by forming LiF into a thin film having an average film thickness of 0.5 nm by the vacuum deposition method at a deposition rate of 1 Å/sec.

After that, the second electron injection layer 13b was formed. The second electron injection layer 13b was formed as a film having an average film thickness of 1 nm by the vacuum deposition method. The film formation conditions were that the deposition rate of Al was 1 [Å/sec]; for the Mg—Ag alloy (1:9), the deposition rate of Mg was 0.1 [Å/sec] and the deposition rate of Ag was 0.9 [Å/sec]; for the Mg—Ag alloy (9:1), the deposition rate of Ag was 0.1 [Å/sec] and the deposition rate of Mg was 0.9 [Å/sec]; and the deposition rate of Cs₂CO₃ was 0.1 [Å/sec].

Lastly, the cathode 15 was formed.

The cathode 15 was formed by forming Ag into a film having an average film thickness of 19 nm, at a deposition rate of 0.9 [Å/sec].

In the organic EL display devices 100 formed thereby, the electron injection layer 13 having a structure of (first electron injection layer 13a)/(second electron injection layer 13b)=LiF/Al is also referred to as an element A; the electron injection layer 13 having a structure of only Cs₂CO₃ is also referred to as an element B; the electron injection layer 13 having a structure of (first electron injection layer 13a)/(second electron injection layer 13b)=LiF/Mg—Ag (1:9) is also referred to as an element C; and the electron injection layer 13 having a structure of (first electron injection layer 13a)/(second electron injection layer 13b)=LiF/Mg—Ag (9:1) is also referred to as an element D.

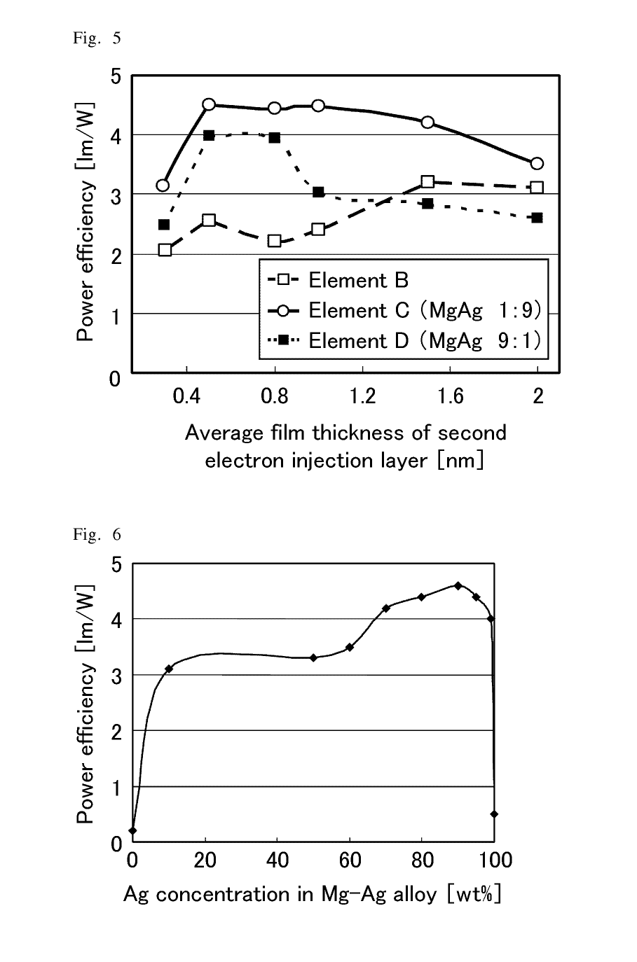

The properties of the organic EL display devices 100 including the respective elements A to D were compared. FIG. 4 shows the measurement results obtained. FIG. 4 is a graph illustrating the drive voltage, current efficiency, and power efficiency of each element. The graph in FIG. 4 shows that the organic EL display device 100 including the element C had the highest power efficiency. In the case of EODs 200, the EOD 200 including the structure of LiF/Mg—Ag (9:1), i.e. the element D, showed the highest electron injection properties. However, the initial properties of the element D were not so good in the case of the organic EL display device 100. The element B showed high current efficiency, but showed high drive voltage which resulted in low power efficiency.

The reflectance, transmittance, and absorptance of the semi-transparent electrode of each element were measured. The following Table 1 shows the measurement results obtained. The reflectance and transmittance were determined by measuring the visible light transmission spectrum at the wavelengths of 380 nm to 780 nm by a spectrophotometer (product of Hitachi High-Technologies Corp., model number: U-4100). The absorptance was determined from the following formula.

Absorptance={100%−(reflectance+transmittance)}

TABLE 1

| | Reflectance | Transmittance | Absorptance |
|---|---|---|---|
| | (%) | (%) | (%) |
| Element A | N/A | N/A | N/A |
| Element B | 35.2 | 44.4 | 20.4 |
| Element C | 31.7 | 45.5 | 22.8 |
| Element D | 26.5 | 40.4 | 33.1 |

From the results shown in FIG. 4 and Table 1, a conclusion can be drawn that the element B having the lowest light absorptance gave a good result in terms of the current efficiency; the element B, however, had the highest drive voltage, and therefore showed low power efficiency. The highest drive voltage is probably caused by the lowest electron injection efficiency of the element B in the EOD 200.

In comparison of the element C and the element D, the element D had high light absorptance because of the low Ag blending ratio, which is probably a cause of the better initial properties of the element C than those of the element D. These results clearly show that the composition of the second electron injection layer 13b is very important even though the layer has a very thin average film thickness of about 1 nm.

Next, the power efficiency of the organic EL display devices 100 including the element B, element C, and element D was measured in each case that the average film thickness of the second electron injection layer 13b was changed to a value in the range of 0.3 nm to 2.0 nm. FIG. 5 shows the measurement results obtained.

FIG. 5 is a graph illustrating the relation between the average film thickness and power efficiency of each second electron injection layer 13b. The element B, which had the lowest power efficiency among the three elements as described above, was revealed to have better power efficiency as the average film thickness increased.

In comparison of the element C and the element D, the element C having a higher Ag concentration showed higher power efficiency than the element D, in every average film thickness of the second electron injection layer 13b. The element C had particularly high power efficiency in the case that the second electron injection layer 13b had an average film thickness of 0.5 nm to 1.5 nm. The element C was found to have a tendency of having lower power efficiency when the average film thickness of the second electron injection layer 13b was more than 1.5 nm, and this tendency was notable when the average film thickness was 2 nm. Also in the case that the average film thickness was too small, that is, in the case that the average film thickness was less than 0.5 nm, the electron injection properties were found to be decreased.

The above results show that the composition of the second electron injection layer 13b and control of the film thickness of the layer are very important for the organic EL display device 100.

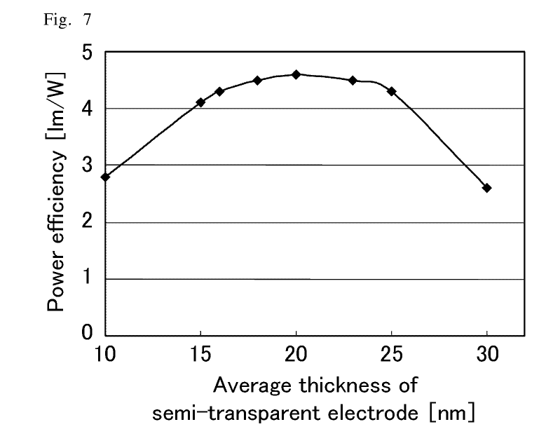

Next, the effect of the amount of Ag on the power efficiency in a thin film made of an Mg—Ag alloy was determined. More specifically, the power efficiency was measured by forming the second electron injection layer 13b as a thin film made of an Mg—Ag alloy, and changing the Ag concentration in the thin film in the range of 0 wt % to 100 wt %. The average film thickness of the second electron injection layer 13b was 1.0 nm. The average film thickness of the cathode 15 made of Ag was 19 nm. FIG. 6 shows the measurement results obtained.

FIG. 6 is a graph illustrating the relation between the Ag concentration and power efficiency in an Mg—Ag alloy. The measurement results in FIG. 6 show that high power efficiency was obtained when the Ag concentration was in the range of 70 wt % to 99 wt %.

Also, the relation between the power efficiency and the average film thickness of the semi-transparent electrode, i.e., the average total film thickness of the cathode 15 and the electron injection layer 13 was examined. More specifically, the semi-transparent electrode had a structure in which the first electron injection layer 13a was formed as a thin film of LiF and had an average film thickness of 0.5 nm; the second electron injection layer 13b was formed as a thin film of Mg—Ag (1:9) and had an average film thickness of 1 nm; and the cathode 15 made of Ag had an average film thickness that gave an average total film thickness of the cathode 15 and the electron injection layer 13 of 10 nm to 30 nm. A change in the power efficiency in such a structure with different cathode 15 thicknesses was determined. FIG. 7 shows the measurement results obtained.

FIG. 7 is a graph illustrating the relation between the average film thickness and power efficiency of a semi-transparent electrode. The measurement results in FIG. 7 revealed that high power efficiency could be achieved when the semi-transparent electrode had an average film thickness in the range of 15 nm to 25 nm, particularly in the range of 17 nm to 23 nm. The average film thickness of the semi-transparent electrode in the range of 15 nm to 17 nm can be employed in the case that the original spectrum is narrow and the chromaticity is good. The average film thickness in the range of 23 nm to 25 nm can be employed in the case that the original spectrum is broad and the chromaticity is bad.

The above results show that, in the present embodiment, the composition of the semi-transparent cathode, i.e., the electron injection layer 13 and the cathode 15, was preferably the first electron injection layer 13a/second electron injection layer 13b/cathode 15=LiF/Mg—Ag(1:9)/Ag, and the average film thickness of the semi-transparent cathode was preferably in the range of 15 nm to 25 nm. One preferred example of the semi-transparent cathode in the present embodiment is a semi-transparent cathode in which the first electron injection layer 13a is a thin film of LiF having an average film thickness of 0.5 nm, the second electron injection layer 13b is a thin film of Mg—Ag (1:9) having an average film thickness of 0.5 nm to 1.5 nm, and the cathode 15 is a thin film of Ag having a film thickness of 19 nm.

In the above embodiment, the cathode 15 made of Ag was given as an example, but the cathode 15 may be one made of an Mg—Ag alloy. In that case, in terms of properties such as the light reflectivity, light absorptivity, and electron injection properties, the Ag concentration in the Mg—Ag alloy constituting the cathode 15 is preferably more than 70 wt % and less than 100 wt %, provided that the concentration is not less than the Ag concentration in the second electron injection layer 13b.

Although no thin-film transistors (TFTs) were formed on the substrate 10 in the above embodiment, TFTs may be formed.

Also in the above embodiment, an example was given in which the second electron injection layer 13b was made of Mg—Ag (1:9). The example, however, is not intended to limit the present invention, and the composition (blending ratio) of the Mg—Ag alloy can be appropriately determined.

Each of the structures used in the above embodiment may be appropriately combined as long as the combination does not go beyond the scope of the present invention.

The present application claims priority to Patent Application No. 2009-176872 filed in Japan on Jul. 29, 2009 under the Paris Convention and provisions of national law in a designated State, the entire contents of which are hereby incorporated by reference.

### EXPLANATION OF SYMBOLS

10 Substrate
11, 220 Anode
12 Organic layer
13, 250 Electron injection layer
13a First electron injection layer
13b Second electron injection layer
15, 260 Cathode
21 Hole injection layer
22 Hole transport layer
23 Light-emitting layer
24, 240 Electron transport layer
100 Organic EL display device
200 EOD
210 Glass substrate
230 LiF layer

1. An organic electroluminescent display device, comprising
an organic electroluminescent element that includes an anode, an organic layer, an electron injection layer, and a cathode stacked in this order toward a viewing side,
wherein the cathode is a thin film made of silver or a silver alloy,
the electron injection layer includes a first electron injection layer arranged on the organic layer side and a second electron injection layer arranged on the cathode side,
the first electron injection layer is formed as a thin film containing lithium fluoride,
the second electron injection layer is formed as a thin film containing a magnesium-silver alloy that has a silver concentration of more than 70 wt % and less than 100 wt %, and an average total film thickness of the cathode and the electron injection layer is not less than 15 nm and not more than 25 nm.

2. The organic electroluminescent display device according to claim 1, wherein an average film thickness of the second electron injection layer is not less than 0.5 nm and not more than 1.5 nm.

3. The organic electroluminescent display device according to claim 1,
wherein an average total film thickness of the cathode and the electron injection layer is not less than 17 nm and not more than 23 nm.

4. The organic electroluminescent display device according to claim 1,
wherein the cathode is formed as a thin film containing a magnesium-silver alloy that has a silver concentration of more than 70 wt % and less than 100 wt %, provided that the concentration is not less than the silver concentration of the second electron injection layer.

5. An organic electroluminescent device, comprising
an organic electroluminescent element that includes an anode, an organic layer, an electron injection layer, and a cathode stacked in this order toward a viewing side,
wherein the cathode is a thin film made of silver or a silver alloy,
the electron injection layer includes a first electron injection layer arranged on the organic layer side and a second electron injection layer arranged on the cathode side,
the first electron injection layer is formed as a thin film containing lithium fluoride,
the second electron injection layer is formed as a thin film containing a magnesium-silver alloy that has a silver concentration of more than 70 wt % and less than 100 wt %, and
an average total film thickness of the cathode and the electron injection layer is not less than 15 nm and not more than 25 nm.
